(19) United States
(12) Patent Application Publication
(10) Pub. No.: US 2024/0111211 A1
(43) Pub. Date: Apr. 4, 2024

(54) PHOTOSENSITIVE RESIN FILM, RESIST PATTERN FORMING METHOD, AND WIRING PATTERN FORMING METHOD

(71) Applicant: Showa Denko Materials Co., Ltd., Tokyo (JP)

(72) Inventors: Tatsuhiko ARAI, Tokyo (JP); Fuuka HIRAYAMA, Tokyo (JP); Keishi ONO, Tokyo (JP); Mao NARITA, Tokyo (JP); Takahiro FUKAYA, Tokyo (JP)

(21) Appl. No.: 17/767,655

(22) PCT Filed: Oct. 16, 2019
(86) PCT No.: PCT/JP2019/040754

§ 371 Date: Apr. 8, 2022

(51) Int. Cl. G03F 7/031

(52) U.S. Cl. CPC G03F 7/031

(57) ABSTRACT

The present disclosure relates to a photosensitive resin film containing a binder polymer, a photopolymerizable compound, a photopolymerization initiator, and a polymerization inhibitor and having a thickness of 35 to 300 μm.

### TECHNICAL FIELD

The present disclosure relates to a photosensitive resin film, a method for forming a resist pattern, and a method for forming a wiring pattern.

### BACKGROUND ART

In the field of manufacturing semiconductor integrated circuits (LSI) or wiring boards, photosensitive materials have been used as resists for producing conductor patterns. For example, in the manufacture of a wiring board, a resist is formed using a photosensitive resin composition, and subsequently a conductor pattern, a metal post, or the like is formed by a plating treatment. More specifically, a resist pattern (resist) is formed on a substrate by forming a photosensitive layer using a photosensitive resin composition or the like, exposing the photosensitive layer through a predetermined mask pattern, and then performing a developing treatment so that a portion forming a conductor pattern, a metal post, or the like can be selectively removed (peeled). Next, a conductor such as copper is formed by a plating treatment in this removed portion, subsequently the resist pattern is removed, and thereby a wiring board including a conductor pattern, a metal post, or the like can be manufactured (see, for example, Patent Literatures 1 and 2).

### CITATION LIST

### Patent Literature

Patent Literature 1: JP 2000-356852 A
Patent Literature 2: WO 2008/064803 A1

### SUMMARY OF INVENTION

### Technical Problem

In recent years, with regard to electronic components such as an inductor, investigations have been conducted on making the thickness of the conductor layer thicker and forming a wiring pattern having a high aspect ratio. However, in conventional thick-film photosensitive resists, it is difficult for light to pass to the bottom of the photosensitive layer, and the pattern shape may be deteriorated. Accordingly, there is a demand for a photosensitive resin film having excellent pattern forming properties despite being a thick film.

The present disclosure was achieved in view of the above-described circumstances, and it is an object of the present disclosure to provide a photosensitive resin film having excellent pattern forming properties, a method for forming a resist pattern using this photosensitive resin film, and a method for forming a wiring pattern.

### Solution to Problem

A photosensitive resin film according to the present disclosure contains a binder polymer, a photopolymerizable compound, a photopolymerization initiator, and a polymerization inhibitor and has a thickness of 35 to 300 μm.

The polymerization inhibitor may include a catechol compound. The content of the polymerization inhibitor may be 0.01 to 0.3 parts by mass with respect to 100 parts by mass of the total amount of the binder polymer and the photopolymerizable compound.

The photosensitive resin film may further contain a pyrazoline compound as a photosensitizer.

The photopolymerizable compound may include a (meth)acrylate having a urethane bond and may include a polyalkylene glycol di(meth)acrylate.

A method for forming a resist pattern according to the present disclosure includes a step of providing a photosensitive layer on a substrate using the above-mentioned photosensitive resin film; a step of irradiating at least a portion of the photosensitive layer with active rays to form a photocured part; and a step of removing at least a portion other than the photocured part in the photosensitive layer and forming a resist pattern.

A method for forming a wiring pattern according to the present disclosure has a step of subjecting a substrate having a resist pattern formed by the above-described method for forming a resist pattern, to a plating treatment to form a conductor pattern. The method for forming a wiring pattern may further include a step of removing the photocured part, after the plating treatment.

### Advantageous Effects of Invention

According to the present disclosure, a photosensitive resin film having excellent pattern forming properties, a method for forming a resist pattern using this photosensitive resin film, and a method for forming a wiring pattern, can be provided.

### BRIEF DESCRIPTION OF DRAWINGS

FIG. 1 is a schematic cross-sectional view illustrating an embodiment of a photosensitive resin film.

FIG. 2 is a diagram schematically illustrating an embodiment of a step of forming a wiring pattern.

### DESCRIPTION OF EMBODIMENTS

The present disclosure will be described in detail below. In the present specification, a numerical value range expressed using the term “to” represents a range including the numerical values described before and after the term “to” as the minimum value and the maximum value, respectively. Furthermore, in a numerical value range described stepwise in the present specification, the upper limit value or the lower limit value of the numerical value range of a certain stage may be replaced with the upper limit value or the lower limit value of the numerical value range of another stage. With regard to a numerical value range described in the present specification, the upper limit value or the lower limit value of the numerical value range may be replaced with a value shown in the Examples.

According to the present specification, the term “(meth)acrylic acid” means at least one of “acrylic acid” and “methacrylic acid” corresponding thereto, and the same also applies to other similar expressions such as (meth)acrylate.

According to the present specification, the term “solid content” is the content of non-volatile components excluding volatile substances such as water and solvents, which are included in the photosensitive resin composition, and represents components that remain without volatilizing when the resin composition is dried, and the components also include substances that are liquid, syruβ-like, and waxy at room temperature near 25° C.

[Photosensitive Resin Film]

The photosensitive resin film according to the present embodiment contains a binder polymer, a photopolymerizable compound, a photopolymerization initiator, and a polymerization inhibitor and has a thickness of 35 to 300 μm. The photosensitive resin film can be produced using a photosensitive resin composition containing a binder polymer, a photopolymerizable compound, a photopolymerization initiator, and a polymerization inhibitor. In the following description, the various components used for the photosensitive resin film and the photosensitive resin composition according to the present embodiment will be described in detail.

((A) Binder Polymer)

(A) Binder polymer (hereinafter, may also be referred to as “component (A)”) can be manufactured by, for example, subjecting a polymerizable monomer to radical polymerization. Examples of the polymerizable monomer include styrene or a styrene derivative; an acrylamide such as diacetone acrylamide; acrylonitrile; an ether of vinyl alcohol, such as vinyl-n-butyl ether; a (meth)acrylic acid alkyl ester, (meth)acrylic acid benzyl ester, (meth)acrylic acid tetrahydrofurfuryl ester, (meth)acrylic acid dimethyl aminoethyl ester, (meth)acrylic acid diethylaminoethyl ester, (meth)acrylic acid glycidyl ester, 2,2,2-trifluoroethyl (meth)acrylate, 2,2,3,3-tetrafluoropropyl (meth)acrylate, (meth)acrylic acid, α-bromoacrylic acid, α-chloracrylic acid, β-furyl (meth)acrylic acid, β-styryl (meth)acrylic acid, maleic acid, maleic anhydride, maleic acid monoesters such as monomethyl maleate, monoethyl maleate, and monoisopropyl maleate, fumaric acid, cinnamic acid, α-cyanocinnamic acid, itaconic acid, crotonic acid, and propiolic acid. The polymerizable monomers can be used singly or in combination of two or more kinds thereof.

The component (A) may have a carboxy group, from the viewpoint of alkali developability. The component (A) having a carboxy group can be manufactured by, for example, subjecting a polymerizable monomer having a carboxy group and another polymerizable monomer to radical polymerization. The polymerizable monomer having a carboxy group may be (meth)acrylic acid or may be methacrylic acid.

From the viewpoint of enhancing alkali developability and alkali resistance in a well-balanced manner, the content of a structural unit based on a polymerizable monomer having a carboxy group may be 10% to 50% by mass, 15% to 40% by mass, or 20% to 35% by mass, based on the total amount of the component (A). When the carboxy group content is 10% by mass or more, alkali developability tends to be enhanced, and when the carboxy group content is 50% by mass or less, alkali resistance tends to be excellent.

The acid value of the component (A) having a carboxy group may be 50 to 250 mg KOH/g, 50 to 200 mg KOH/g, or 100 to 200 mg KOH/g.

From the viewpoints of close adhesiveness and peeling characteristics, the component (A) may have a structural unit based on styrene or a styrene derivative. A styrene derivative is a polymerizable compound in which the α-position or a hydrogen atom in the aromatic ring of styrene has been substituted, such as vinyltoluene or α-methylstyrene. The content of the structural unit based on styrene or a styrene derivative in the component (A) may be 10% to 60% by mass, 15% to 50% by mass, 35% to 50% by mass, or 40% to 50% by mass. When this content is 10% by mass or more, close adhesiveness tends to be enhanced, and when the content is 60% by mass or less, peeled pieces can be suppressed from becoming large at the time of developing, and prolongation of the time required for peeling tends to be suppressed.

From the viewpoints of resolution and the aspect ratio, the component (A) may have a structural unit based on (meth)acrylic acid benzyl ester. From the viewpoint of enhancing the resolution and the aspect ratio, the content of the structural unit derived from (meth)acrylic acid benzyl ester in the component (A) may be 10% to 40% by mass, 15% to 35% by mass, or 20% to 30% by mass.

From the viewpoint of enhancing plasticity, the component (A) may have a structural unit based on a (meth)acrylic acid alkyl ester. Examples of the (meth)acrylic acid alkyl ester include (meth)acrylic acid methyl ester, (meth)acrylic acid ethyl ester, (meth)acrylic acid propyl ester, (meth)acrylic acid butyl ester, (meth)acrylic acid pentyl ester, (meth)acrylic acid hexyl ester, (meth)acrylic acid heptyl ester, (meth)acrylic acid octyl ester, (meth)acrylic acid 2-ethylhexyl ester, (meth)acrylic acid nonyl ester, (meth)acrylic acid decyl ester, (meth)acrylic acid undecyl ester, and (meth)acrylic acid dodecyl ester.

The weight average molecular weight (Mw) of the component (A) may be 10000 to 300000, 150000 to 150000, 200000 to 100000, or 25000 to 80000. When the Mw of the component (A) is 10000 or more, liquid developer resistance tends to be excellent, and when the Mw is 300000 or less, prolongation of the developing time tends to be suppressed. Regarding the component (A), the degree of dispersion (weight average molecular weight/number average molecular weight) may be 1.0 to 3.0 or 1.0 to 2.0. When the degree of dispersion is decreased, resolution tends to be enhanced.

The weight average molecular weight and the number average molecular weight according to the present specification are values measured by gel permeation chromatography (GPC) and calculated relative to polystyrene standards as standard samples.

Regarding the component (A), one kind thereof can be used alone, or two or more kinds thereof can be used in combination. Examples of the component (A) in the case of using two or more kinds thereof in combination include two or more kinds of binder polymers formed from different polymerizable monomers, two or more kinds of binder polymers having different Mw values, and two or more kinds of binder polymers having different degrees of dispersion.

The content of the component (A) may be 30 to 80 parts by mass, to 75 parts by mass, 50 to 70 parts by mass, or 50 to 60 parts by mass, with respect to 100 parts by mass of the total amount of the component (A) and the component (B) that will be described below. When the content of the component (A) is in this range, the strength of the photosensitive resin film and the photocured part of the photosensitive layer is further improved.

((B) Photopolymerizable Compound)

As (B) photopolymerizable compound (hereinafter, also referred to as “component (B)”), a compound having at least one ethylenically unsaturated bond in the molecule can be used. Regarding the component (B), one kind thereof can be used alone, or two or more kinds thereof can be used in combination.

The ethylenically unsaturated bond of the component (B) is not particularly limited as long as it is capable of photopolymerization. Examples of the ethylenically unsaturated bond include an α,β-unsaturated carbonyl group such as a (meth)acryloyl group. Examples of the photopolymerizable compound having an α,β-unsaturated carbonyl group include an α,β-unsaturated carboxylic acid ester of a polyhydric alcohol, a bisphenol type (meth)acrylate, an α,β-unsaturated carboxylic acid adduct of a glycidyl group-containing compound, a (meth)acrylate having a urethane bond, nonylphenoxy polyethylene oxyacrylate, a (meth)acrylate having a phthalic acid skeleton, and a (meth)acrylic acid alkyl ester.

Examples of the α,β-unsaturated carboxylic acid ester of a polyhydric alcohol include polyethylene glycol di(meth)acrylate in which the number of ethylene groups is 2 to 14, polypropylene glycol di(meth)acrylate in which the number of propylene groups is 2 to 14, polyethylene-polypropylene glycol di(meth)acrylate in which the number of ethylene groups is 2 to 14 and the number of propylene groups is 2 to 14, trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, tetramethylolmethane tri(meth)acrylate, tetramethylolmethane tetra(meth)acrylate, and a (meth)acrylate compound having a skeleton derived from dipentaerythritol or pentaerythritol. The term “EO-modified” means that the compound has a block structure of an ethylene oxide (EO) group, and the term “PO-modified” means that the compound has a block structure of a propylene oxide (PO) group.

From the viewpoint of enhancing flexibility of the resist pattern, the component (B) may include a polyalkylene glycol di(meth)acrylate. The polyalkylene glycol di(meth)acrylate may have at least one of an EO group and a PO group or may have both an EO group and a PO group. With regard to a polyalkylene glycol di(meth)acrylate having both an EO group and a PO group, the EO group and the PO group may be each present continuously in a block form or may be present randomly. Furthermore, the PO group may be any of an oxy-n-propylene group or an oxyisopropylene group. Incidentally, in the (poly)oxyisopropylene group, the secondary carbon of the propylene group may be bonded to an oxygen atom, or a primary carbon may be bonded to an oxygen atom.

Examples of a commercially available product of the polyalkylene glycol di(meth)acrylate include FA-023M (manufactured by Hitachi, Ltd.), FA-024M (manufactured by Hitachi, Ltd.), and NK ESTER HEMA-9P (manufactured by Shin-Nakamura Chemical Co., Ltd.).

From the viewpoint of enhancing flexibility of the resist pattern, the component (B) may include a (meth)acrylate having a urethane bond. Examples of the (meth)acrylate having a urethane bond include an addition reaction product of a (meth)acrylic monomer having an OH group at the β-position and a diisocyanate (isophorone diisocyanate, 2,6-toluene diisocyanate, 2,4-toluene diisocyanate, 1,6-hexamethylene diisocyanate, or the like), tris((meth)acryloxytetraethylene glycol isocyanate) hexamethylene isocyanurate, EO-modified urethane di(meth)acrylate, and EO- and PO-modified urethane di(meth)acrylate.

Examples of a commercially available product of the EO-modified urethane di(meth)acrylate include “UA-11” and “UA-21EB” (manufactured by Shin-Nakamura Chemical Co., Ltd.). Examples of a commercially available product of the EO- and PO-modified urethane di(meth)acrylate include “UA-13” (manufactured by Shin-Nakamura Chemical Co., Ltd.).

From the viewpoint that a thick-film resist pattern is easily formed, and that resolution and close adhesiveness are enhanced in a well-balanced manner, the component (B) may include a (meth)acrylate compound having a skeleton derived from dipentaerythritol or pentaerythritol. It is preferable that the (meth)acrylate compound having a skeleton derived from dipentaerythritol or pentaerythritol has four or more (meth)acryloyl groups, and this (meth)acrylate compound may be dipentaerythritol penta(meth)acrylate or dipentaerythritol hexa(meth)acrylate.

As the component (B), a polyfunctional (meth)acrylate compound that is obtainable by reacting a polyhydric alcohol with an α,β-unsaturated carboxylic acid, may be included. The polyfunctional (meth)acrylate compound may have at least one of an EO group and a PO group or may have both an EO group and a PO group. Regarding such a compound, dipentaerythritol (meth)acrylate having an EO group or the like can be used. Examples of a commercially available product of dipentaerythritol (meth)acrylate having an EO group include DPEA-12 (manufactured by Nippon Kayaku Co., Ltd.).

From the viewpoint of enhancing resolution and the peeling characteristics after curing, the component (B) may include a bisphenol type (meth)acrylate, and among bisphenol type (meth)acrylates, the component (B) may include bisphenol A type (meth)acrylate. Examples of bisphenol A type (meth)acrylate include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane. Among them, 2,2-bis(4-((meth)acryloxypolyethoxy)phenyl)propane is preferred from the viewpoint of further enhancing resolution and pattern forming properties.

Examples of commercially available products include BPE-200 (Shin-Nakamura Chemical Co., Ltd.) for 2,2-bis(4-((meth)acryloxydipropoxy)phenyl)propane, and BPE-500 (Shin-Nakamura Chemical Co., Ltd.) and FA-321M (Hitachi Chemical Co., Ltd.) for 2,2-bis(4-(methacryloxypentaethoxy)phenyl)propane.

Examples of nonylphenoxy polyethyleneoxy acrylate include nonylphenoxy tetraethyleneoxy acrylate, nonylphenoxy pentaethyleneoxy acrylate, nonylphenoxy pentaethyleneoxy acrylate, nonylphenoxy hexaethyleneoxy acrylate, nonylphenoxy heptaethyleneoxy acrylate, nonylphenoxy octaethyleneoxy acrylate, nonylphenoxy nonaethyleneoxy acrylate, nonylphenoxy decaethyleneoxy acrylate, and nonylphenoxy undecaethyleneoxy acrylate.

Examples of a (meth)acrylate having a phthalic acid skeleton include γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate. γ-Chloro-β-hydroxypropyl-β′-methacryloyloxyethyl-o-phthalate is commercially available as FA-MECH (Hitachi Chemical Co., Ltd.).

((C) Photopolymerization Initiator)

(C) Photopolymerization initiator (hereinafter, also referred to as “component (C)”) is not particularly limited as long as it can polymerize the component (B), and the (C) photopolymerization initiator can be appropriately selected from conventionally used photopolymerization initiators. From the viewpoint of enhancing sensitivity and resolution in a well-balanced manner, the component (C), the component (C) may include a hexaarylbiimidazole derivative or an acridine compound having one or more acridinyl group. Regarding the component (C), one kind thereof can be used alone, or two or more kinds thereof can be used in combination.

Examples of the hexaarylbiimidazole derivative include 2-(o-chlorophenyl)-4,5-diphenylbiimidazole, 2,2′,5-tris(o-chlorophenyl)-4-(3,4-dimethoxyphenyl)-4′,5′-diphenylbiimidazole, 2,4-bis(o-chlorophenyl)-5-(3,4-dimethoxyphenyl)-diphenylbiimidazole, 2,4,5-tris(o-chlorophenyl)-diphenylbiimidazole, 2-(o-chlorophenyl)-bis-4,5-(3,4-dimethoxyphenyl)-biimidazole, 2,2′-bis(2-fluorophenyl)-4,4′,5,5′-tetrakis(3-methoxyphenyl)-biimidazole, 2,2′-bis(2,3-difluoromethylphenyl)-4,4′,5,5′-tetrakis(3-methoxyphenyl)-biimidazole, 2,2′-bis(2,4-difluorophenyl)-4,4′,5,5′-tetrakis(3-methoxyphenyl)-biimidazole, and 2,2′-bis(2,5-difluorophenyl)-4,4′,5,5′-tetrakis(3-methoxyphenyl)-biimidazole.

Examples of the acridine compound include 9-phenylacridine, 9-(β-methylphenyl)acridine, 9-(m-methylphenyl)acridine, 9(β-chlorophenyl)acridine, 9-(m-chlorophenyl)acridine, 9-aminoacridine, 9-dimethylaminoacridine, 9-diethylaminoacridine, 9-pentylaminoacridine; bis(9-acridinyl)alkanes such as 1,2-bis(9-acridinyl)ethane, 1,4-bis(9-acridinyl)butane, 1,6-bis(9-acridinyl)hexane, 1,8-bis(9-acridinyl)octane, 1,10-bis(9-acridinyl)decane, 1,12-bis(9-acridinyl)dodecane, 1,14-bis(9-acridinyl)tetradecane, 1,16-bis(9-acridinyl)hexadecane, 1,18-bis(9-acridinyl)octadecane, and 1,20-bis(9-acridinyl)eicosane; 1,3-bis(9-acridinyl)-2-oxapropane, 1,3-bis(9-acridinyl)-2-thiapropane, and 1,5-bis(9-acridinyl)-3-thiapentane.

The content of the component (C) may be 0.1 to 10 parts by mass, 1 to 5 parts by mass, or 2 to 4.5 parts by mass, with respect to 100 parts by mass of the total amount of the component (A) and the component (B). When the content of the component (C) is 0.1 parts by mass or more, photosensitivity, resolution, and close adhesiveness tend to be enhanced, and when the content is 10 parts by mass or less, the resist pattern forming properties tend to be superior.

((D) Polymerization Inhibitor)

The photosensitive resin film according to the present embodiment can have enhanced pattern forming properties by containing (D) polymerization inhibitor (hereinafter, also referred to as “component (D)”). Regarding the component (D), one kind thereof can be used alone, or two or more kinds thereof can be used in combination.

From the viewpoint of further enhancing the pattern forming properties, the component (D) may include a compound represented by the following Formula (I):

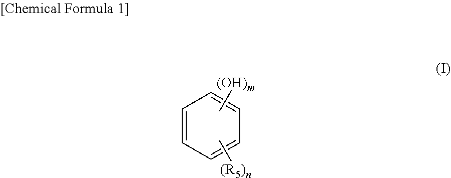

In Formula (I), R⁵ represents a halogen atom, a hydrogen atom, an alkyl group having 1 to 20 carbon atoms, a cycloalkyl group having 3 to 10 carbon atoms, an amino group, an aryl group, a mercapto group, an alkylmercapto group having 1 to 10 carbon atoms, a carboxylalkyl group having an alkyl group having 1 to 10 carbon atoms, an alkoxy group having 1 to 20 carbon atoms, or a heterocyclic group; m and n are such that m represents an integer of 2 or more, n represents an integer of 0 or more, and m and n are selected so as to satisfy m+n=6; and when n is an integer of 2 or more, R⁵'s may be respectively identical or different. Incidentally, the aryl group may be substituted with an alkyl group having 1 to 20 carbon atoms.

From the viewpoint of further enhancing compatibility with the component (A), R⁵ may be a hydrogen atom or an alkyl group having 1 to 20 carbon atoms. The alkyl group having 1 to 20 carbon atoms as represented by R⁵ may be an alkyl group having 1 to 4 carbon atoms. From the viewpoint of further enhancing resolution, m may be 2 or 3, or may be 2.

Examples of the compound represented by the above-described General Formula (I) include catechol compounds such as catechol, 2-methylcatechol, 3-methylcatechol, 4-methylcatechol, 2-ethylcatechol, 3-ethylcatechol, 4-ethylcatechol, 2-propylcatechol, 3-propylcatechol, 4-propylcatechol, 2-n-butylcatechol, 3-n-butylcatechol, 4-n-butylcatechol, 2-tert-butylcatechol, 3-tert-butylcatechol, 4-tert-butylcatechol, and 3,5-di-tert-butylcatechol; resorcinol compounds such as resorcinol (resorcin), 2-methylresorcinol, 4-methylresorcinol, 5-methylresorcinol (orcin), 2-ethylresorcinol, 4-ethylresorcinol, 2-propylresorcinol, 4-propylresorcinol, 2-n-butylresorcinol, 4-n-butylresorcinol, 2-tert-butylresorcinol, and 4-tert-butylresorcinol; hydroquinone compounds such as 1,4-hydroquinone, methylhydroquinone, ethylhydroquinone, propylhydroquinone, tert-butylhydroquinone, and 2,5-di-tert-butylhydroquinone; and trivalent phenol compounds such as pyrogallol and phloroglucinol.

From the viewpoint of enhancing resolution, the component (D) may include a catechol compound. The catechol compound is preferably an alkylcatechol such as 2-methylcatechol, 3-methylcatechol, 4-methylcatechol, 2-ethylcatechol, 3-ethylcatechol, 4-ethylcatechol, 2-propylcatechol, 3-propylcatechol, 4-propylcatechol, 2-n-butylcatechol, 3-n-butylcatechol, 4-n-butylcatechol, 2-tert-butylcatechol, 3-tert-butylcatechol, 4-tert-butylcatechol, or 3,5-di-tert-butylcatechol, and more preferably 3-tert-butylcatechol, 4-tert-butylcatechol, or 3,5-di-tert-butylcatechol.

The content of the component (D) may be 0.01 to 0.3 parts by mass, 0.02 to 0.2 parts by mass, 0.025 to 0.15 parts by mass, or 0.03 to 0.1 parts by mass, with respect to 100 parts by mass of the total amount of the component (A) and the component (B). When the content of the component (D) is adjusted to 0.3 parts by mass or less, the exposure time can be shortened. When the content of the component (D) is adjusted to 0.01 parts by mass or more, the photoreaction of the photocured part can be sufficiently carried out, and the pattern forming properties can be further increased.

(Component (E): Photosensitizer)

The photosensitive resin film and the photosensitive resin composition according to the present embodiment may further contain (E) photosensitizer (hereinafter, also referred to as “component (E)”). By incorporating the component (E), the absorption wavelength of the active rays used for exposure can be effectively utilized. Regarding the component (E), one kind thereof can be used alone, or two or more kinds thereof can be used in combination.

Examples of the component (E) include a dialkylaminobenzophenone compound, a pyrazoline compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compound, a thiophene compound, a naphthalimide compound, a triarylamine compound, and an aminoacridine compound. From the viewpoint of further enhancing the resolution, the component (E) may include a pyrazoline compound.

Examples of the pyrazoline compound include 1-(4-methoxyphenyl)-3-styryl-5-phenyl-pyrazoline, 1-phenyl-3-(4-methoxystyryl)-5-(4-methoxyphenyl)-pyrazoline, 1,5-bis(4-methoxyphenyl)-3-(4-methoxystyryl)-pyrazoline, 1-(4-isopropylphenyl)-3-styryl-5-phenyl-pyrazoline, 1-phenyl-3-(4-isopropylstyryl)-5-(4-isopropylphenyl)-pyrazoline, 1,5-bis(4-isopropylphenyl)-3-(4-isopropylstyryl)-pyrazoline, 1-(4-methoxyphenyl)-3-(4-tert-butylstyryl)-5-(4-tert-butyl-phenyl)-pyrazoline, 1-(4-tert-butyl-phenyl)-3-(4-methoxystyryl)-5-(4-methoxyphenyl)-pyrazoline, 1-(4-isopropyl-phenyl)-3-(4-tert-butylstyryl)-5-(4-tert-butyl-phenyl)-pyrazoline, 1-(4-tert-butyl-phenyl)-3-(4-isopropylstyryl)-5-(4-isopropylphenyl)-pyrazoline, 1-(4-methoxyphenyl)-3-(4-isopropylstyryl)-5-(4-isopropylphenyl)-pyrazoline, 1-(4-isopropyl-phenyl)-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, 1-phenyl-3-(2,4-dimethoxystyryl)-5-(2,4-dimethoxyphenyl)-pyrazoline, 1-(4-methoxyphenyl)-3-(3,5-dimethoxystyryl)-5-(3,5-dimethoxyphenyl)-pyrazoline, 1-(4-methoxyphenyl)-3-(3,4-dimethoxystyryl)-5-(3,4-dimethoxyphenyl)-pyrazoline, 1-(4-methoxyphenyl)-3-(2,6-dimethoxystyryl)-5-(2,6-dimethoxyphenyl)-pyrazoline, 1-(4-methoxyphenyl)-3-(2,5-dimethoxystyryl)-5-(2,5-dimethoxyphenyl)-pyrazoline, 1-(4-methoxyphenyl)-3-(2,3-dimethoxystyryl)-5-(2,3-dimethoxyphenyl)-pyrazoline, 1-(4-methoxyphenyl)-3-(2,4-dimethoxystyryl)-5-(2,4-dimethoxyphenyl)-pyrazoline, 1-(4-tert-butyl-phenyl)-3-(3,5-dimethoxystyryl)-5-(3,5-dimethoxyphenyl)-pyrazoline, 1-(4-tert-butyl-phenyl)-3-(3,4-dimethoxystyryl)-5-(3,4-dimethoxyphenyl)-pyrazoline, 1-(4-tert-butyl-phenyl)-3-(2,6-dimethoxystyryl)-5-(2,6-dimethoxyphenyl)-pyrazoline, 1-(4-tert-butyl-phenyl)-3-(2,5-dimethoxystyryl)-5-(2,5-dimethoxyphenyl)-pyrazoline, 1-(4-tert-butyl-phenyl)-3-(2,3-dimethoxystyryl)-5-(2,3-dimethoxyphenyl)-pyrazoline, 1-(4-tert-butyl-phenyl)-3-(2,4-dimethoxystyryl)-5-(2,4-dimethoxyphenyl)-pyrazoline, 1-(4-isopropylphenyl)-3-(3,5-dimethoxystyryl)-5-(3,5-dimethoxyphenyl)-pyrazoline, 1-(4-isopropylphenyl)-3-(3,4-dimethoxystyryl)-5-(3,4-dimethoxyphenyl)-pyrazoline, 1-(4-isopropylphenyl)-3-(2,6-dimethoxystyryl)-5-(2,6-dimethoxyphenyl)-pyrazoline, 1-(4-isopropylphenyl)-3-(2,5-dimethoxystyryl)-5-(2,5-dimethoxyphenyl)-pyrazoline, 1-(4-isopropylphenyl)-3-(2,3-dimethoxystyryl)-5-(2,3-dimethoxyphenyl)-pyrazoline, and 1-(4-isopropylphenyl)-3-(2,4-dimethoxystyryl)-5-(2,4-dimethoxyphenyl)-pyrazoline.

From the viewpoint of enhancing the ease of synthesis and sensitivity, 1-phenyl-3-(4-methoxystyryl)-5-(4-methoxyphenyl)-pyrazoline is preferred, and from the viewpoint of enhancing the ease of synthesis and solubility, 1-phenyl-3-(4-isopropylstyryl)-5-(4-isopropylphenyl)-pyrazoline is preferred.

From the viewpoint of enhancing photosensitivity and resolution, the content of the component (E) may be 0.01 to 5 parts by mass, 0.01 to 1 part by mass, or 0.01 to 0.2 parts by mass, with respect to 100 parts by mass of the total amount of the component (A) and the component (B).

(Other Components)

The photosensitive resin film and the photosensitive resin composition according to the present embodiment may further contain Leuco crystal violet in addition to the above-mentioned various components. As a result, the photosensitivity and resolution of the photosensitive resin film can be enhanced in a more well-balanced manner. Leuco crystal violet has a property as a photo color developer, which absorbs light and develops a specific color, and it can be considered that the above-described effect can be provided due to that property.

The content of Leuco crystal violet may be 0.01 to 10 parts by mass, 0.05 to 5 parts by mass, or 0.1 to 3 parts by mass, with respect to 100 parts by mass of the total amount of the component (A) and the component (B).

The photosensitive resin film and the photosensitive resin composition of the present embodiment may further contain a dye such as Malachite green; tribromophenylsulfone; a photo color developer other than Leuco crystal violet; a thermal color development inhibitor, a plasticizer such as β-toluenesulfonamide; a pigment, a filler, an antifoaming agent, a flame retardant, a stabilizer, an adhesion imparting agent, a leveling agent, a peeling promoting agent, an oxidation inhibitor, a fragrance, an imaging agent, a thermal crosslinking agent, and the like as necessary.

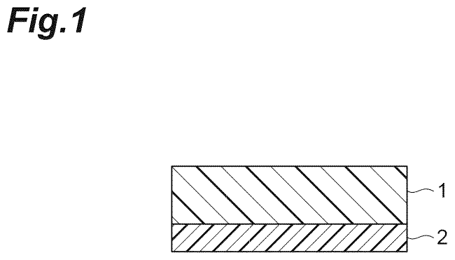

FIG. 1 is a schematic cross-sectional view illustrating an embodiment of the photosensitive resin film. The photosensitive resin film 1 according to the present embodiment may be formed on a support film 2 by using the above-mentioned photosensitive resin composition. The photosensitive resin film according to the present embodiment can be used in the form of a photosensitive element including a support film 2 and a photosensitive resin film 1 provided on the support film 2, as shown in FIG. 1.

The thickness of the photosensitive resin film 1 is 35 to 300 μm. From the viewpoint of the pattern forming properties for a wiring pattern with a high aspect ratio, the thickness of the photosensitive resin film 1 may be 40 μm or more, 45 μm or more, or 50 μm or more. From the viewpoint of peelability of the photosensitive resin film, the thickness of the photosensitive resin film 1 may be 250 μm or less, 200 μm or less, or 150 μm or less.

Examples of the support film include films of polyesters such as polyethylene terephthalate (PET), polybutylene terephthalate (PBT), and polyethylene-2,6-naphthalate (PEN); and films of polyolefins such as polypropylene and polyethylene.

The Haze of the support film may be 0.01% to 5.0%, 0.01% to 1.5%, 0.01% to 1.0%, or 0.01% to 0.5%. The haze refers to a value measured according to the method stipulated in JIS K7105 using a commercially available haze meter (turbidity meter). The haze can be measured with, for example, a commercially available turbidity meter such as NDH-5000 (manufactured by Nippon Denshoku Industries Co., Ltd., trade name).

The thickness of the support film may be 1 to 200 μm, 1 to 100 μm, 1 to 60 μm, 5 to 60 μm, 10 to 60 μm, 10 to 50 μm, 10 to 40 μm, 10 to 30 μm, or 10 to 25 μm. When the thickness of the support film is 1 μm or more, there is a tendency that when the support film is peeled off, breakage of the support film can be suppressed. Furthermore, when the thickness of the support film is 200 μm or less, there is a tendency that economic benefits are likely to be obtained.

On the surface of the photosensitive resin film 1 opposite to the support film 2, a protective film may be laminated. As the protective film, a film of a polymer such as polyethylene or polypropylene may be used. A polymer film similar to the support film may be used, or a different polymer film may be used. It is preferable that the adhesive force between the protective film and the photosensitive resin film 1 is smaller than the adhesive force between the support film 2 and the photosensitive resin film 1.

The photosensitive resin film 1 can be formed by, for example, applying the photosensitive resin composition on the support film 2 and then drying the photosensitive resin composition. Application can be carried out using, for example, a known method such as roll coating, comma coating, gravure coating, air knife coating, die coating, or bar coating. Drying can be carried out at 70° C. to 150° C. for about 5 to 30 minutes.

When the photosensitive resin composition is applied on the support film 2, if necessary, a solvent may be added to the photosensitive resin composition so as to use a solution having a solid content of about 30% to 60% by mass. Examples of the solvent include methanol, ethanol, acetone, methyl ethyl ketone, methyl cellosolve, ethyl cellosolve, toluene, N,N-dimethylformamide, and propylene glycol monomethyl ether. The solvents can be used singly or in combination of two or more kinds thereof. In this case, it is preferable that the residual solvent amount in the photosensitive resin film is adjusted to 2% by mass or less, in order to prevent diffusion of the solvent in the subsequent steps.

The form of the photosensitive element is not particularly limited. For example, the photosensitive element may be in a sheet form or may be in the form of being wound around a winding core into a roll. In the case of being wound into a roll, the photosensitive element may be wound such that the support film comes to the outer side. The winding core may be, for example, a plastic such as a polyethylene resin, a polypropylene resin, a polystyrene resin, a polyvinyl chloride resin, or an ABS resin (acrylonitrile-butadiene-styrene copolymer).

At the end-faces of the roll-shaped photosensitive element, end-face separators may be provided from the viewpoint of protecting the end-faces, or moisture-proof end-face separators may be provided from the viewpoint of edge fusion resistance. The photosensitive element may also be packaged by wrapping with a black sheet having low moisture permeability.

Since the photosensitive resin film according to the present embodiment has excellent pattern forming properties, a resist pattern having a high aspect ratio can be formed.

[Method for Forming Resist Pattern]

A method for forming a resist pattern according to the present embodiment includes a step of providing a photosensitive layer on a substrate using the above-mentioned photosensitive resin film (hereinafter, also referred to as “photosensitivity forming step”); a step of irradiating at least a portion of the photosensitive layer with active rays to form a photocured part (hereinafter, also referred to as “exposure step”); and a step of removing at least a portion other than the photocured part in the photosensitive layer and forming a resist pattern (hereinafter, also referred to as “developing step”). The resist pattern is also referred to as a photocured product pattern of the photosensitive resin film or is also referred to as a relief pattern. Furthermore, the method for forming a resist pattern can also be referred to as a method for manufacturing a resist pattern-attached substrate.

With regard to the photosensitive layer forming step, in the case of using the above-described photosensitive element, when the photosensitive element has a protective film, this protective film is first removed, a photosensitive resin film is pressure-bonded to a substrate at a pressure of about 0.1 to 1 MPa (about 1 to 10 kgf/cm²) to be laminated thereon under reduced pressure or at normal pressure while heating the photosensitive resin film to about 70° C. to 130° C., and a photosensitive layer is formed on the substrate. Regarding the substrate, for example, a copper-clad laminated plate in which copper foil is provided on one surface or both surfaces of a layer formed from an insulating material such as a glass fiber-reinforced epoxy resin, is used.

In the exposure step, the photosensitive layer is exposed to active rays after removing the support film or through the support film. Examples of a method for exposure include a method of irradiating the photosensitive layer with active rays into an image form through a negative or positive mas pattern called artwork (mask exposure method), a method of irradiating the photosensitive layer with active rays by a projection exposure method, and a method of irradiating the photosensitive layer with active rays into an image form by a direct drawing exposure method such as an LDI (Laser Direct Imaging) exposure method or a DLP (Digital Light Processing) exposure method.

Regarding the light source of the active rays, any known light source can be used, and for example, a light source that effectively radiates ultraviolet radiation and visible light, such as a carbon arc lamp, a mercury vapor arc lamp, a high-pressure mercury lamp, a xenon lamp, a gas laser such as argon laser, a solid laser such as YAG laser, or a semiconductor laser, is used.

From the viewpoint of enhancing close adhesiveness, after exposure, post-exposure heating (PEB: Post exposure bake) may be carried out before developing. The temperature in the case of performing PEB may be 50° C. to 100° C. As the heating machine, a hot plate, a compartment dryer, a heating roll, or the like may be used.

In the developing step, as at least a portion other than the photocured part in the above-described photosensitive layer is removed from the substrate, a resist pattern is formed on the substrate.

When a support film is present on the photosensitive layer, after the support film is removed, removal (developing) of a region other than the photocured part (may also be referred to as unexposed portion) is carried out. Examples of developing methods include wet developing and dry developing; however, wet developing is widely used.

In the case of adopting wet developing, developing is performed by any known developing method by using a liquid developer that is compliant to the photosensitive resin composition. Examples of the developing method include a dipping method, a puddle method, a spraying method, and methods using brushing, slapping, scrubbing, rocking immersion, or the like, and from the viewpoint of enhancing resolution, a high-pressure spraying method may be used. Developing may be carried out by using any two or more kinds of these methods in combination.

The configuration of the liquid developer is appropriately selected according to the configuration of the photosensitive resin composition. Examples of the liquid developer include an alkaline aqueous solution and an organic solvent liquid developer.

From the viewpoint of being safe and stable and having satisfactory operability, an alkaline aqueous solution may be used as the liquid developer. Examples of the base of the alkaline aqueous solution include an alkali hydroxide such as hydroxide of lithium, sodium, or potassium; an alkali carbonate such as carbonate or bicarbonate of lithium, sodium, potassium, or ammonium; an alkali metal phosphate such as potassium phosphate or sodium phosphate; an alkali metal pyrophosphate such as sodium pyrophosphate or potassium pyrophosphate; borax, sodium metasilicate, tetramethylammonium hydroxide, ethanolamine, ethylenediamine, diethylenetriamine, 2-amino-2-hydroxymethyl-1,3-propanediol, 1,3-diaminopropanol-1, and morpholine.

Examples of the alkaline aqueous solution used for developing include a 0.1 mass % to 5 mass % aqueous solution of sodium carbonate, a 0.1 mass % to 5 mass % aqueous solution of potassium carbonate, and a 0.1 mass % to 5 mass % aqueous solution of sodium hydroxide. The pH of the alkaline aqueous solution may be in the range of 9 to 11, and the temperature of the alkaline aqueous solution can be regulated according to the developability of the photosensitive layer.

Into the alkaline aqueous solution, for example, a surface-active agent, an antifoaming agent, and a small amount of an organic solvent for promoting developing may be incorporated. Examples of the organic solvent used for the alkaline aqueous solution include acetone, ethyl acetate, an alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether. Examples of the organic solvent used for the organic solvent liquid developer include 1,1,1-trichloroethane, N-methylpyrrolidone, N,N-dimethylformamide, cyclohexanone, methyl isobutyl ketone, and γ-butyrolactone. The organic solvent may be prepared into an organic solvent liquid developer by adding water such that the content of water is in the range of 1% to 20% by mass, in order to prevent ignition.

The method for forming a resist pattern according to the present embodiment may include, after removing the uncured portion in the developing step, a step of further curing the resist pattern by heating at about 60° C. to 250° C. or performing exposure at about 0.2 to 10 J/cm², as necessary.

[Method for Forming Wiring Pattern]

A method for forming a wiring pattern according to the present embodiment includes a step of subjecting a substrate having a resist pattern formed thereon by the above-described method for forming a resist pattern, to a plating treatment to form a conductor pattern. The method for forming a wiring pattern may further include a step of removing a photocured part, after the plating treatment.

In the plating treatment, the resist pattern formed on the substrate including a conductor layer is used as a mask, and the conductor layer of the substrate that is not covered by the resist is plated with copper, solder, or the like. After the plating treatment, the resist is removed by the removal of the resist pattern as will be described below, and the conductor layer covered by this resist is further etched to form a conductor pattern.

Regarding the method for the plating treatment, the plating treatment may be an electroplating treatment or an electroless plating treatment; however, above all, an electroless plating treatment may be used. Examples of the electroless plating treatment include copper plating such as copper sulfate plating or copper pyrophosphate plating; solder plating such as high throw solder plating; nickel plating such as Watts bath (nickel sulfate-nickel chloride) plating or nickel sulfamate plating; and gold plating such as hard gold plating or soft gold plating.

After the above-described plating treatment, the resist pattern on the substrate is removed. For the removal of the resist pattern, for example, the resist pattern can be peeled off using a stronger alkaline aqueous solution than the alkaline aqueous solution used in the developing step. Regarding this strong alkaline aqueous solution, for example, a 1 mass % to 10 mass % aqueous solution of sodium hydroxide or a 1 mass % to 10 mass % aqueous solution of potassium hydroxide is used. Among these, a 1 mass % to 5 mass % aqueous solution of sodium hydroxide or aqueous solution of potassium hydroxide may be used.

When the resist pattern has been removed after being subjected to a plating treatment, a desired printed wiring board can be manufactured by further etching the resist-covered conductor layer by an etching treatment and forming a conductor pattern. The method for the etching treatment at this time is appropriately selected according to the conductor layer to be removed. For example, the above-mentioned etching solution can be applied.

Examples of the method for removing the resist pattern include an immersion method and a spraying method, and these may be used singly or in combination.

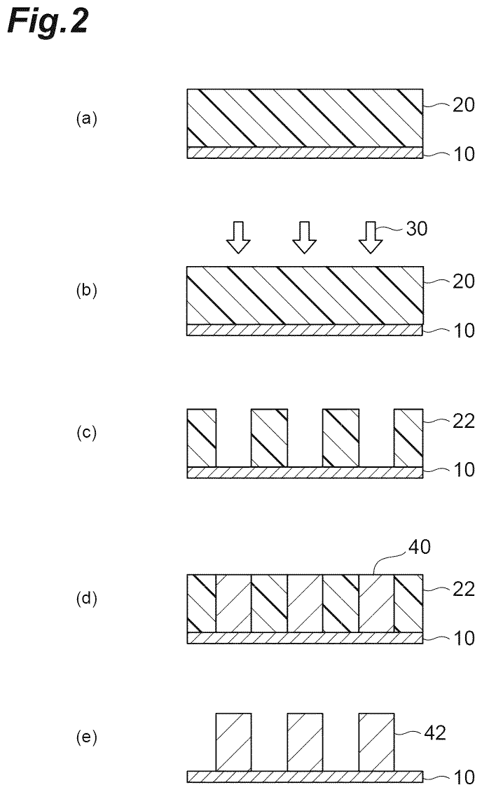

An embodiment of the step of forming a wiring pattern using the photosensitive resin film according to the present embodiment is shown in FIG. 2.

In FIG. 2(a), a photosensitive resin film 1 is laminated on a substrate 10 having a conductor layer formed on an insulating layer to form a photosensitive layer 20 by the above-described photosensitive layer forming step. In FIG. 2(b), the photosensitive layer 20 is irradiated with active rays 30 to form a photocured part on the photosensitive layer by the above-described exposure step. In FIG. 2(c), a resist pattern 22, which is the photocured part, is formed on the substrate 10 by removing regions other than the photocured part formed by the above-described exposure step from the substrate by a developing step. In FIG. 2(d), a plating layer 40 is formed on the substrate 10 that is not covered by the resist, by a plating treatment of using the resist pattern 22 as a mask. In FIG. 2(e), the resist pattern 22, which is the photocured part, is peeled by a strong alkaline aqueous solution to form a conductor pattern 42.

Since the photosensitive resin film according to the present embodiment has excellent pattern forming properties even when formed into a thick film, the photosensitive resin film can be suitably used for the production of, for example, an electronic circuit board such as an inductor, or the like.

### EXAMPLES

Hereinafter, the object and advantages of the present embodiment will be described more specifically based on Examples and Comparative Examples; however, the present embodiment is not intended to be limited to the following Examples.

### Production of Photosensitive Resin Film

### Examples 1 to 5 and Comparative Example 1

The various components shown in Table 1 were mixed at the mixing amounts shown in the same table (the unit for the numerical values in the table is parts by mass, and in the case of a solution, the mixing amount is an amount calculated relative to the solid content), and solutions of photosensitive resin compositions were prepared.

A solution of a photosensitive resin composition was uniformly applied on a polyethylene terephthalate (PET) film having a thickness of 16 μm (manufactured by Toray Industries, Inc., trade name: FB-40) and dried for 10 minutes at 70° C. and for 10 minutes at 100° C. using a hot air convection type dryer, to form a photosensitive resin film formed from the above-described photosensitive resin composition on one surface of the PET film as a support film.

The details of the respective components shown in Table 1 are as follows.

(Component (A))
A-1: Ethylene glycol monomethyl ether-toluene solution (solid content: 47% by mass) of a copolymer of methacrylic acid-styrene-benzyl methacrylate (mass ratio: 32/45/23, Mw: 51000)

(Component (B))
FA-321M: 2,2-Bis(4-(methacryloxypentaethoxy)phenyl)propane (Hitachi Chemical Co., Ltd., number of EO groups: 10 (average value))
FA-024M: Polyalkylene glycol dimethacrylate (Hitachi Chemical Co., Ltd., number of EO groups: 12 (average value), number of PO groups: 4 (average value))
DPEA-12: Dipentaerythritol hexaacrylate having EO groups (Nippon Kayaku Co., Ltd., number of EO groups: 12 (average value))
UA-21EB: Triacrylate having a urethane bond (Shin-Nakamura Chemical Co., Ltd.)

(Component (C): Photopolymerization initiator)
B-CIM: 2,2′-Bis(2-chlorophenyl)-4,4′,5,5′-tetraphenylbiimidazole (Changzhou Tronly New Electronic Materials Co., Ltd.)

(Component (D): Polymerization inhibitor)
TBC: 4-tert-butylcatechol (DIC Corporation)

(Component (E): Photosensitizer)
PZ-501D: 1-Phenyl-3-(4-methoxystyryl)-5-(4-methoxyphenyl)pyrazoline (Nippon Chemical Works Co., Ltd.)

(Color Developer)
LCV: Leuco crystal violet (Yamada Chemical Co., Ltd.) (Dye)
MKG: Malachite green (Osaka Organic Chemical Industry, Ltd.) (Adhesion imparting agent)
SF-808H: Mixture of carboxybenzotriazole, 5-amino-1H-tetrazole, and methoxypropanol (Sanwa Chemical Co., Ltd.)

[Resolution]

A copper-clad laminated plate (manufactured by Hitachi Chemical Co., Ltd., trade name “MCL-E-67”) in which copper foil (thickness: 12 μm) was laminated on both surfaces of a glass fiber-reinforced epoxy resin layer, was washed with water, washed with acid, and washed with water, and then the copper-clad laminated plate was dried with an air stream. Next, the copper-clad laminated plate was heated to 80° C., and a photosensitive resin film was laminated on the copper surface of the copper-clad laminated plate. Lamination was carried out using a heat roll at 110° C. at a pressure-bonding pressure of 0.4 MPa and a roll speed of 1.0 m/min. In this manner, a laminated body in which a copper-clad laminated plate, a photosensitive layer, and a PET film were laminated in this order was obtained.

On the PET film of the laminated body, a photo tool having a 41-stage step tablet having a concentration region of 0.00 to 2.00, a concentration step of 0.05, a tablet size of 20 mm×187 mm, and a size of 3 mm×12 mm for each step as a negative mask was placed. Next, the photosensitive layer was exposed with a predetermined energy amount using a parallel beam exposure apparatus having a high-pressure mercury lamp as a light source (manufactured by ORC Manufacturing Co., Ltd., trade name “EXM-1201”).

On the PET film of the laminated body, Photomask Hitachi Test Patterns No. G2 (negative for resolution evaluation: having a wiring pattern with a line width/space width of x/x (x: 30 to 200, unit: μm)) and No. 3 (negative for resolution evaluation: having a wiring pattern with a line width/space width of x/x (x: 6 to 47, unit: μm)) were used as negatives for resolution evaluation, and exposure was performed with an energy amount by which the number of residual step stages after developing of the Hitachi 41-stage step tablet became 14.0. After the exposure, the PET film was peeled off, a 1 mass % aqueous solution of sodium carbonate at 30° C. was sprayed for a time twice the shortest developing time (shortest time required for removing unexposed portions), and unexposed portions were removed.

After the developing treatment, in a resist pattern from which space portions (unexposed portions) were neatly removed and line portions (exposed portions) were formed without causing meandering and chipping, the resolution was evaluated based on the smallest value of line width/space width. The resolution was evaluated based on the minimum value of the space width. As this numerical value is smaller, it is implied that resolution is more satisfactory.

[Flexibility]

The copper-clad laminated plate was changed to an FPC substrate (manufactured by Nikkan Industries Co., Ltd., trade name: F-30VC1, substrate thickness: 25 μm, copper thickness: 18 μm) to obtain a laminated body in which an FPC substrate, a photosensitive layer, and a PET film were laminated in this order.

Exposure was performed through the PET film side of the laminated body, by using a parallel beam exposure apparatus (EXM-1201) with an energy amount by which the number of residual step stages after developing of the 41-stage step tablet became 14 stages, and the photosensitive layer was photocured. Then, after the PET film was peeled off, developing was performed to obtain a substrate for bendability evaluation, in which a resist pattern having a size of 10 mm×100 mm was formed on the FPC substrate.

The substrate for bendability evaluation was reciprocatingly rubbed against a cylindrical-shaped rod at 180°, and then the minimum cylinder diameter (mm) at which peeling between the FPC substrate and the resist pattern did not occur, was determined. Evaluation was performed with cylinder diameters of 2, 3, 4, 5, 6, 8, 9, 10, 11, 12, 13, 15, 20, 25, and 30 (unit: mm). As the minimum diameter of the cylinder was smaller, it is implied that flexibility is superior. In a case where evaluation was performed with a cylinder having a diameter of 30 mm, when peeling between the FPC base material and the resist layer was confirmed, the evaluation result was expressed as “>30”.

TABLE 1

| | | | | | | | Comparative |
|---|---|---|---|---|---|---|---|
| | | Example 1 | Example 2 | Example 3 | Example 4 | Example 5 | Example 1 |
| Component (A) | A-1 | 57 | 57 | 57 | 57 | 57 | 57 |
| Component (B) | FA-321M | 18 | 18 | 18 | 18 | 18 | 18 |
| | FA-024M | 18 | 18 | 18 | 18 | — | 18 |
| | DPEA-12 | 4 | 4 | 4 | 4 | 4 | 4 |
| | UA-21EB | 3 | 3 | 3 | 3 | — | 3 |
| Component (C) | B-CIM | 2.9 | 2.9 | 2.9 | 2.9 | 2.9 | 2.9 |
| Component (D) | TBC | 0.05 | 0.15 | 0.05 | 0.05 | 0.05 | — |
| Component (E) | PZ-501D | 0.02 | 0.02 | 0.02 | 0.02 | 0.02 | 0.02 |
| Color developer | LCV | 0.5 | 0.5 | 0.5 | 0.5 | 0.5 | 0.5 |
| Dye | MKG | 0.05 | 0.05 | 0.05 | 0.05 | 0.05 | 0.05 |
| Adhesion | SF-808H | 1.0 | 1.0 | 1.0 | 1.0 | 1.0 | 1.0 |
| imparting agent | | | | | | | |

| | | | | | | |
|---|---|---|---|---|---|---|
| Film thickness (μm) | 50 | 50 | 100 | 150 | 150 | 150 |
| Resolution (μm/μm) | 20/20 | 20/20 | 40/40 | 70/70 | 70/70 | 100/100 |
| Aspect ratio | 2.5 | 2.5 | 2.5 | 2.1 | 2.1 | 1.5 |
| Flexibility (ϕmm) | 8 | 8 | 20 | 25 | >30 | 25 |

### REFERENCE SIGNS LIST

1: photosensitive resin film, 2: support film, 10: substrate, 20: photosensitive layer, 22: resist pattern, 30: active rays, 40: plating layer, 42: conductor pattern.

1. A photosensitive resin film containing a binder polymer, a photopolymerizable compound, a photopolymerization initiator, and a polymerization inhibitor and having a thickness of 35 to 300 μm.

2. The photosensitive resin film according to claim 1, wherein the polymerization inhibitor includes a catechol compound.

3. The photosensitive resin film according to claim 1, wherein the content of the polymerization inhibitor is 0.01 to 0.3 parts by mass with respect to 100 parts by mass of the total amount of the binder polymer and the photopolymerizable compound.

4. The photosensitive resin film according to claim 1, further containing a pyrazoline compound as a photosensitizer.

5. The photosensitive resin film according to claim 1, wherein the photopolymerizable compound includes a (meth)acrylate having a urethane bond.

6. The photosensitive resin film according to claim 1, wherein the photopolymerizable compound includes a polyalkylene glycol di(meth)acrylate.

7. A method for forming a resist pattern, the method comprising:
a step of providing a photosensitive layer on a substrate using the photosensitive resin film according to claim 1;
a step of irradiating at least a portion of the photosensitive layer with active rays to form a photocured part; and
a step of removing at least a portion other than the photocured part in the photosensitive layer and forming a resist pattern.

8. A method for forming a wiring pattern, the method comprising a step of subjecting a substrate having a resist pattern formed thereon by the method for forming a resist pattern according to claim 7, to a plating treatment to form a conductor pattern.

9. The method for forming a wiring pattern according to claim 8, further comprising a step of removing the photocured part, after the plating treatment.

10. The photosensitive resin film according to claim 2, wherein the content of the polymerization inhibitor is 0.01 to 0.3 parts by mass with respect to 100 parts by mass of the total amount of the binder polymer and the photopolymerizable compound.
